(19) United States
(12) Patent Application Publication
(10) Pub. No.: US 2014/0334181 A1
(43) Pub. Date: Nov. 13, 2014

(54) BACKLIGHT UNIT OF DISPLAY DEVICE AND WHITE LED

(71) Applicants: Che chang HU, Shenzhen (CN); Yong FAN, Shenzhen (CN)

(72) Inventors: Che chang HU, Shenzhen (CN); Yong FAN, Shenzhen (CN)

(73) Assignee: SHENZHEN CHINA STAR OPTOELECTRONICS TECHNOLOGY CO., LTD, Shenzhen (CN)

(21) Appl. No.: 13/985,291

(22) PCT Filed: Jun. 28, 2013
(86) PCT No.: PCT/CN2013/078282

§ 371 Date: Aug. 14, 2013

(30) Foreign Application Priority Data
May 8, 2013 (CN) 201310167073.5

(51) Int. Cl. F21V 8/00; H01L 33/04

(52) U.S. Cl. CPC G02B 6/0026; G02B 6/0013; H01L 33/04; Y10S 977/774; B82Y 20/00
USPC 362/608; 257/13; 977/774

(57) ABSTRACT

A backlight unit of a display device includes a light bar and a light guide plate (LGP), where a plurality of ultraviolet (UV) light emitting diodes (LEDs) are arranged on the light bar, and a light incident surface of the LGP and the UV LEDs are oppositely arranged. at least one red-green-blue (RGB) quantum dot phosphor layer is arranged in a path of a light from the UV LEDs to a light emitting surface of the LGP. The RGB quantum dot phosphor layer comprises a red quantum dot fluorescence film, a green quantum dot fluorescence film, and a blue quantum dot fluorescence film that are successively arranged.

### TECHNICAL FIELD

The present disclosure relates to the field of a display device, and more particularly to a backlight unit of the display device and a white light emitting diode (LED).

### BACKGROUND

A typical color thin film transistor (TFT) liquid crystal display (LCD) device usually uses a white light emitting diode (LED) collocated with a colored red-green-blue (RGB) photoresist, which allows the TFT-LCD device to display a color picture. In order to make the TFT-LCD device to display a picture having more colors, namely an area of color displayed is great in a chromaticity coordinate of the international commission on illumination (CIE), and a white LED having a great RGB purity is used.

Two methods are used to obtain the white LED having the great RGB purity. A first method uses an LED having a tri-color chip, where the tri-color chip includes a red chip, a green chip, and a blue chip. A second method uses a blue chip and a red-green (RG) phosphor. In the first method, working lives of the red chip, the green chip, and the blue chip are different, especially the working life of the green chip is the shortest, which affects brightness and chroma of the white LED, thus chroma detection is used to adjust a driving current in the first method, which increases manufacturing cost. Compared with the first method, the second method is usually used by the white LED having the great RGB purity. However the second method allows an area increase of color that is displayed of the TFT-LCD device to be limited when color filter (CF) is the same. Compared with a yellow LED display device, the white LED using the second method only increases less than 20% saturation of national television standards committee NTSC when the CF is same.

CN Pub. No. CN2593229Y provides a method for exciting a red-green-blue (RGB) phosphor arranged on a light guide plate (LGP) through an ultraviolet (UV) LED, where the RGB phosphor are coated on the LGP after the red phosphor, the green phosphor, and the blue phosphor are proportionally mixed. However, the method may cause reabsorption of the red phosphor and the green phosphor, thereby reducing luminous efficiency.

### SUMMARY

The aim of the present disclosure is to provide a backlight unit of a display device and a white LED capable of great saturation.

the aim of the present disclosure is achieved by the following method.

A backlight unit of a display device comprises a light bar and a light guide plate (LGP), where a plurality of ultraviolet (UV) light emitting diodes (LEDs) are arranged on the light bar, and a light incident surface of the LGP and the UV LEDs are oppositely arranged. At least one red-green-blue (RGB) quantum dot phosphor layer is arranged in a path of a light emitted from the UV LEDs to a light emitting surface of the LGP. The RGB quantum dot phosphor layer comprises a red quantum dot fluorescence film, a green quantum dot fluorescence film, and a blue quantum dot fluorescence film that are successively arranged.

Furthermore, the RGB quantum dot phosphor layer is arranged on the light emitting surface of the LGP. A light of the backlight unit mainly emits from the light emitting surface of the LGP, thus the RGB quantum dot phosphor layer arranged on the light emitting surface of the LGP ensures that the white light is generated.

Furthermore, the RGB quantum dot phosphor layer is arranged on a light incident surface of the LGP. A light emitted from the UV LED of the backlight unit mainly enters into the LGP from the light incident surface of the LGP, then emits from the light emitting surface of the LGP. Thus the RGB quantum dot phosphor layer arranged on the light incident surface of the LGP ensures that a light emitted from the light emitting surface is the white light.

Furthermore, the RGB quantum dot phosphor layer is arranged on a case of the UV LED. The light of the UV LED of the backlight unit emits from the UV LED through the case of the UV LED, thus the RGB quantum dot phosphor layer arranged on the case of the UV LED ensures that a light entering into the LGP and the light emitted from the light emitting surface is the white light.

Furthermore, a diffusion film is arranged on a light emitting surface of the phosphor layer of the RGB-emitting quantum dot. The diffusion film may be used to improve chroma of the light emitted from the LGP.

Furthermore, an increment film is arranged on the light emitting surface of the phosphor layer of the RGB-emitting quantum dot. The increment film may be used to improve brightness of the light emitted from the LGP.

Furthermore, a wavelength of Uv-light emitted from the UV LED is in the range of 360 nm-380 nm.

Furthermore, an emission wavelength of the red quantum dot fluorescence film is in the range of 620 nm-660 nm, a full width at half-maximum (FWHM) of the red quantum dot florescence film is less than 45 nm; an emission wavelength of the green quantum dot fluorescence film is in the range of 520 nm-540 nm, an FWHM of the green quantum dot fluorescence film is less than 45 nm; an emission wavelength of the blue quantum dot fluorescence film is in the range of 440 nm-470 nm, an FWHM of the red quantum dot fluorescence film is less than 40 nm.

Furthermore, the RGB quantum dot phosphor layer is simultaneously arranged on a light incident surface and the light emitting surface of the LGP, which ensures that the light form the LGP is the white light.

Furthermore, a white light emitting diode (LED) comprises an ultraviolet-light (Uv-light) chip and a case, where a red-green-blue (RGB) quantum dot phosphor layer is arranged on the case. The RGB quantum dot phosphor layer comprises a red quantum dot fluorescence film, a green quantum dot fluorescence film, and a blue quantum dot fluorescence film that are successively arranged.

The UV LED is arranged in the light bar of the backlight unit of the present disclosure, at least one RGB quantum dot phosphor layer is arranged in the path of the light emitted from the UV LEDs to the light emitting surface of the LGP. The RGB quantum dot phosphor layer comprises the red quantum dot fluorescence film, the green quantum dot fluorescence film, and the blue quantum dot fluorescence film that are successively arranged. The quantum dot phosphor is different from a common phosphor used on the LED, where the common phosphor used is, such as aluminate phosphor, silicate phosphor, nitride phosphor, and nitrogen oxide phosphor. First, a size of the quantum dot phosphor is usually less than 10 nm, which is less than size of the common phosphor that is between several microns and tens of microns, and the quantum dot phosphor experiences the a quantum size effect, however the common phosphor does not experience the quantum size effect. Second, an FWHM of a luminescence spectrum of the quantum dot phosphor is usually less than 50 nm, and an FWHM of a luminescence spectrum of the common phosphor is usually greater than 50 nm, and is about 100 nm; thus, color purity of light emitted by the quantum dot phosphor is greater than color purity of light emitted by the common phosphor, and the quantum dot phosphor is more suitable than the common phosphor to be used to a liquid crystal backlight source having great saturation. Third, the quantum dot phosphor absorbing the UV-light is greater than the quantum dot phosphor absorbing a blue light of about 450 nm, thus transfer efficiency of exciting the quantum dot phosphor through the UV-light is great, the common phosphor has none of the above-mentioned characteristic. Additionally, the RGB quantum dot phosphor layer of the present disclosure is formed by the red quantum dot fluorescence film, the green quantum dot fluorescence film, and the blue quantum dot fluorescence film that are successively arranged, which improves the saturation of the backlight unit, and avoids reabsorption of the RG quantum dot phosphor, thereby improving the luminous efficiency of the light bar.

### BRIEF DESCRIPTION OF FIGURES

FIG. 1 is a structural diagram of a backlight unit of a first example of the present disclosure.

FIG. 2 is a schematic diagram of a second structure of a red-green-blue (RGB) quantum dot phosphor layer of a second example of the present disclosure.

FIG. 3 is a schematic diagram of a third structure of a red-green-blue (RGB) quantum dot phosphor layer of a third example of the present disclosure.

FIG. 4 is a structural diagram of a white light emitting diode (LED) of a fourth example of the present disclosure.

FIG. 5 is a spectrum diagram of exciting a red-green-blue (RGB) quantum dot phosphor by ultraviolet-light (UV-light).

### DETAILED DESCRIPTION

The present disclosure is further described in detail in accordance with the figures and the exemplary examples.

### EXAMPLE 1

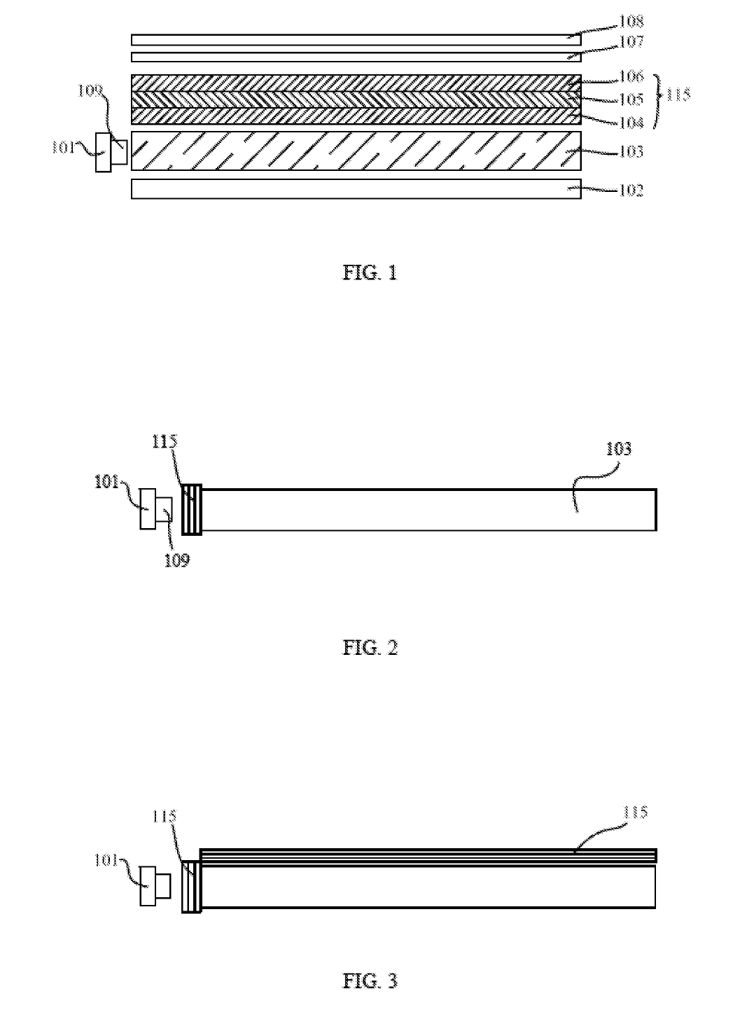

As shown in FIG. 1, a first example provides a backlight unit of a display device, where the backlight unit comprises a light bar 101 and a light guide plate (LGP) 103. A plurality of ultraviolet (UV) light emitting diodes (LEDs) 109 are arranged on the light bar 101, and a light incident surface of the LGP 103 and the UV LEDs 109 are oppositely arranged. A red-green-blue (RGB) quantum dot phosphor layer 115 is arranged in a path of a light emitted from the UV LED 109 to a light emitting surface of the LGP 103, where the RGB quantum dot phosphor layer 115 successively comprises a red quantum dot fluorescence film 104, a green quantum dot fluorescence film 105, and a blue quantum dot fluorescence film 106. The RGB quantum dot phosphor layer 115 is excited to generate white light by UV-light emitted from the UV LED 109, which improves saturation of the backlight unit and avoids reabsorption of a red-green (RG) quantum dot phosphor, thereby improving luminous efficiency of the light bar.

The quantum dot phosphor is different from a common phosphor used on the LED, where the common phosphor used is, such as aluminate phosphor, silicate phosphor, nitride phosphor, and nitrogen oxide phosphor. First, a size of the quantum dot phosphor is usually less than 10 nm, which is less than size of the common phosphor that is between several microns and tens of microns, and the quantum dot phosphor experiences the quantum size effect, however the common phosphor does not experience the quantum size effect. Second, a full width at half-maximum (FWHM) of a luminescence spectrum of the quantum dot phosphor is usually less than 50 nm, and a full width at half-maximum (FWHM) of a luminescence spectrum of the common phosphor is usually greater than 50 nm and is about 100 nm; thus, color purity of light emitted by the quantum dot phosphor is greater than color purity of light emitted by the common phosphor, and the quantum dot phosphor is more suitable than the common phosphor to be used to a liquid crystal backlight source having great saturation. Third, the quantum dot phosphor absorbing the UV-light is greater than the quantum dot phosphor absorbing a blue light of about 450 nm, thus transfer efficiency of exciting the quantum dot phosphor through the UV-light is great, however the common phosphor has none of the above-mentioned characteristic. Additionally, the RGB quantum dot phosphor layer of the first example is formed by the red quantum dot fluorescence film, the green quantum dot fluorescence film, and the blue quantum dot fluorescence film that are successively arranged, which improves the saturation of the backlight unit, and avoids the reabsorption of the RG quantum dot phosphor, thereby improving the luminous efficiency of the light bar.

In the first example, a reflection table 102 is arranged on a surface that is opposite to the light emitting surface of the LGP 103, and light emitted from the surface that is opposite to the light emitting surface of the LGP 103 is reflected into the LGP 103 by the reflection table 102, and is emitted through the light emitting surface of the LGP 103, thereby improving use efficiency of the light. An increment film 107 is arranged on a light emitting surface of the RGB quantum dot phosphor layer 115, and is used to improve brightness of the backlight unit. A diffusion film 108 is also arranged on the light emitting surface of the RGB quantum dot phosphor layer 115, and combines with the increment film 107 to improve evenness and brightness of the backlight unit, thereby improving brightness and chroma of the backlight unit.

In the first example, in order to obtain great saturation, a wavelength of the UV-light emitted from the UV LED is in the range of 360 nm-380 nm. a spectrum diagram of exciting the RGB-emitting quantum dot phosphor by the Uv-light is shown in FIG. 5, an emission wavelength of the red quantum dot fluorescence film is in the range of 620 nm-660 nm, an FWHM of the red quantum dot fluorescence film is less than 45 nm, an emission wavelength of the green quantum dot fluorescence film is in the range of 520 nm-540 nm, an FWHM of the green quantum dot fluorescence film is less than 45 nm, an emission wavelength of the blue quantum dot fluorescence film is in the range of 440 nm-470 nm, an FWHM of blue quantum dot fluorescence film is less than 40 nm.

### EXAMPLE 2

As shown in FIG. 2, the RGB quantum dot phosphor layer 115 is arranged on the light incident surface of the LGP 103 in a second example, which is different from the first example. The light emitted from the UV LED 109 of the backlight unit mainly enters in the LGP 103 from the light incident surface of the LGP 103, and emits from the light emitting surface of the LGP 103. Thus, the RGB quantum dot phosphor layer 115 is arranged on the light incident surface of the LGP 103, which ensures that the light emitted from the light emitting surface of the LGP 103 is the white light. The RGB quantum dot phosphor layer 115 is formed by the red quantum dot fluorescence film 104, the green quantum dot fluorescence film 105, and the blue quantum dot fluorescence film 106 that are successively arranged in light direction.

### EXAMPLE 3

As shown in FIG. 3, the RGB quantum dot phosphor layer 115 is arranged on the light incident surface and the light emitting surface of the LGP 103 in a third example, which is different from the first example and the second example, and ensures that the light form the LGP 103 is the white light.

### EXAMPLE 4

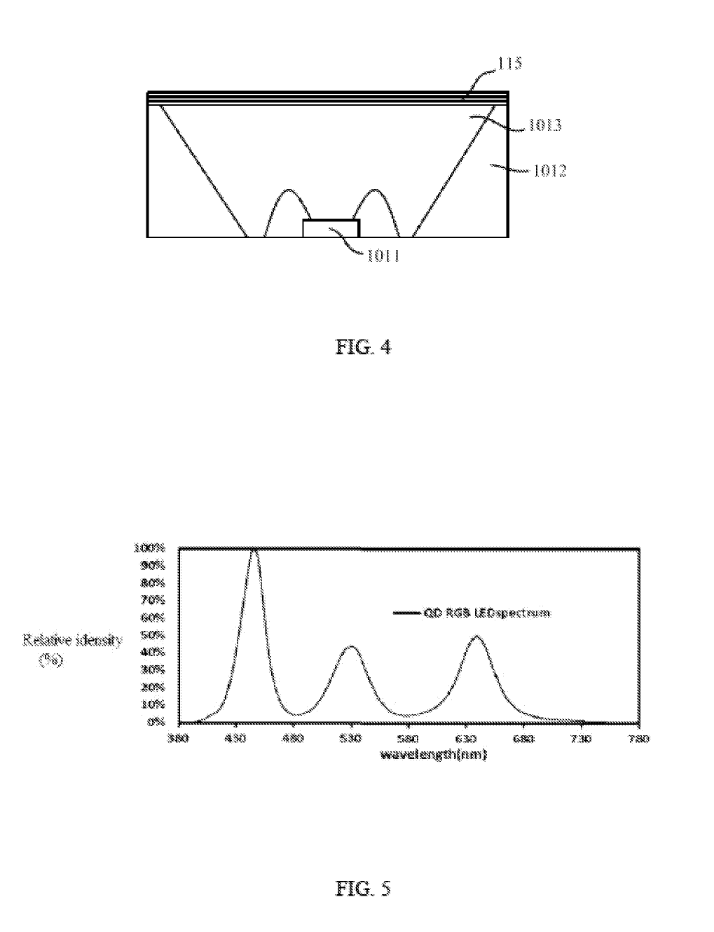

As shown in FIG. 4, a fourth example provides a white LED having an UV-light chip, where the white LED having an UV-light chip comprises the UV-light chip 1011, a coating structure 1012 having UV-resistance, and a case 1013 having UV-resistance. The case 1013 is a rubber having UV-resistance, and the RGB quantum dot phosphor layer 11 is arranged on a surface of the case 1013. The RGB quantum dot phosphor layer 115 is formed by the red quantum dot fluorescence film 104, the green quantum dot fluorescence film 105, and the blue quantum dot fluorescence film 106 that are successively arranged in light direction.

The white LED using the UV-light chip of the fourth example may be used to the backlight unit of the LCD device as point light source of the light bar, and may also be used to other fields, such as lighting.

The present disclosure is described in detail in accordance with the above contents with the specific exemplary examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to he protection scope of the present disclosure.

We claim:

1. A backlight unit of a display device, comprising:
a light bar; and
a light guide plate (LGP);
wherein a plurality of ultraviolet (UV) light emitting diodes (LEDs) are arranged on the light bar, and a light incident surface of the LGP and the UV LEDs are oppositely arranged; at least one red-green-blue (RGB) quantum dot phosphor layer is arranged in a path of light emitted from the UV LEDs to a light emitting surface of the LGP;
wherein the RGB quantum dot phosphor layer comprises a red quantum dot fluorescence film, a green quantum dot fluorescence film, and a blue quantum dot fluorescence film that are successively arranged.

2. The backlight unit of the display device of claim 1, wherein the RGB quantum dot phosphor layer is arranged on the light emitting surface of the LGP.

3. The backlight unit of the display device of claim 1, wherein the RGB quantum dot phosphor layer is arranged on a light incident surface of the LGP.

4. The backlight unit of the display device of claim 1, wherein the RGB quantum dot phosphor layer is arranged on a case of the UV LED.

5. The backlight unit of the display device of claim 1, wherein a diffusion film is arranged on a light emitting surface of the RGB quantum dot phosphor layer.

6. The backlight nit of the display device of claim 5, wherein an increment film is arranged on the light emitting surface of the RGB quantum dot phosphor layer.

7. The backlight unit of the display device of claim 1, wherein wavelength of UV-light emitted from the UV LED is in the range of 360 nm-380 nm.

8. The backlight unit of the display device of claim 7, wherein an emission wavelength of the red quantum dot fluorescence film is in the range of 620 nm-660 nm, a full width at half-maximum (FWHM) of the red quantum dot fluorescence film is less than 45 nm; an emission wavelength of the green quantum dot fluorescence film is in the range of 520 nm-540 nm, an FWHM of the green quantum dot fluorescence film is less than 45 nm; an emission wavelength of the blue quantum dot fluorescence film is in the range of 440 nm-470 nm, an FWHM of the blue quantum dot fluorescence film is less than 40 nm.

9. The backlight unit of the display device of claim 1, wherein the RGB quantum dot phosphor layer is simultaneously arranged on a light incident surface and the light emitting surface of the LGP.

10. A white light emitting diode (LED), comprising:
an ultraviolet-light (Uv-light) chip; and
a case;
wherein a red-green-blue (RGB) quantum dot phosphor layer is arranged on the case; the RGB quantum dot phosphor layer comprises a red quantum dot fluorescence film, a green quantum dot fluorescence film, and a blue quantum dot fluorescence film that are successively arranged.
